(19) United States
(12) Patent Application Publication
(10) Pub. No.: US 2010/0260445 A1
(43) Pub. Date: Oct. 14, 2010

(54) METHOD FOR PRODUCING A SLIDING BEARING ELEMENT HAVING A BISMUTH-CONTAINING SLIDING LAYER

(76) Inventors: Walter Gaertner, Gmunden (AT); Johann Kraemer, Warmbronn (DE); Erwin Schmidt, Baltmannsweiler (DE); Ping Wang, Ulm (DE)

Correspondence Address: COLLARD & ROE, P.C., 1077 NORTHERN BOULEVARD, ROSLYN, NY, 11576, US

(21) Appl. No.: 12/734,081

(22) PCT Filed: Oct. 10, 2008
(86) PCT No.: PCT/AT2008/000366

§ 371 Date: Jun. 8, 2010

(30) Foreign Application Priority Data
Oct. 11, 2007 (AT) A 1635/2007

(51) Int. Cl. F16C 29/02; C23C 14/34

(52) U.S. Cl. 384/7; 204/192.15

(57) ABSTRACT

The invention relates to a method of producing a slide bearing element (1) according to which a sliding layer (6) is produced on a support element (4) by vapour-phase deposition, if necessary after the insertion of at least one intermediate layer, wherein the sliding layer (6) comprises an aluminium matrix, which in addition to aluminium contains bismuth as a main component and possibly copper and also impurities of the elements arising during production. By means of the vapour-phase deposition of at least one element, the melting point of which is at least 950° C. higher than that of the bismuth and/or by applying a bias-voltage to the support element the bismuth-nuclear density is increased.

The invention relates to a method for producing a slide bearing element, according to which a sliding layer is produced on a support element by vapour-phase deposition, if necessary with the inclusion of at least one intermediate layer, wherein the sliding layer comprises an aluminium matrix, which in addition to aluminium contains bismuth as the main component and possibly copper, as well as a slide bearing element with a support element, on which a sliding layer deposited from the vapour phase is formed and if necessary at least one intermediate layer is arranged between the support element and the sliding layer, wherein the sliding layer comprises an aluminium matrix, which in addition to aluminium contains bismuth forming a bismuth-containing phase as the main component and possibly copper.

In the past the sliding layers of slide bearings were usually alloyed with lead as the soft phase element, in order to give the sliding layer on the one hand the desired self-lubricating ability and on the other hand the ability to embed foreign particles caused by abrasion. In addition to this over the course of time also sliding layers have been developed with tin as the soft phase element, whereby tin is inferior to lead with regard to its properties as it has a lower melting point than lead.

Lead is known to be toxic and thus causes environmental problems, which is why its use is becoming less common or is banned by relevant laws or regulations in the automobile business and motor industry.

In earlier patent literature bismuth is also repeatedly referred to as a partial replacement for tin or lead. Bismuth has a melting point which lies between that of tin and lead and is therefore of interest with regard to its use in high-performance engines.

For example DE 32 49 133 C describes a method of producing an aluminium base alloy for composite bearings with 0.5 to 11 wt. % of at least one hard element selected from a group comprising silicon, manganese, iron, molybdenum, nickel, zirconium, cobalt, titanium, antimony, chromium and niobium, wherein the remainder consists of aluminium and unavoidable impurities, by melting, casting, single or multiple rolling with process annealing, whereby to produce substantially spherical hard particles, the greatest diameter of which lies in the range of 5 to 40 μm and which are provided in an area concentration of at least five particles per 3.56×10⁻² mm² in any random part of the alloy, the alloy after the last rolling before the pressure welding with steel support shells is annealed in a temperature range of above 350 to 550° C. for at least one and a half hours and afterwards cooled at a speed of less than 200 ° C. per hour. Said alloy contains 1 to 35 wt. % tin and 0.1 to 10 wt. % of at least one of the elements lead, cadmium, indium, thallium and bismuth.

From DE 36 40 698 C a method is known for producing a bearing alloy with an aluminium base, which consists of at least of one lubricating element selected from the group lead, tin, indium, antimony and bismuth in a total proportion of more than 0.04 but not more than 0.07 cross section area on the total cross sectional area, as well as silicon as the hard element in an amount of 0.01 to 0.17 proportion of the cross sectional area, furthermore as 0.2 to 5 wt. % of at least one strengthening element selected from a group comprising copper, chromium, magnesium, manganese, nickel, tin and iron, as well as 0 to 3 wt. % of at least one grain refining element, selected from a group comprising titanium, boron, zirconium, vanadium, gallium, scandium, yttrium, as well as rare-earth elements with atomic numbers 51 to 71 and aluminium as the remainder, wherein the grain size of the at least one lubricating element is no greater than 8 μm and the grain size of the silicon is no greater than 12 μm and wherein the tensile strength of the alloy at normal temperature is no less than 117 N/mm² and the expansion at normal temperature is no less than 11%. Said bearing alloy is produced by heating a powder of a first alloy with an aluminium base, which consists of 8 to 12 wt. %, 0.4 to 1.8 wt. % tin, 1 to 15 wt. % silicon, 0.2 to 5 wt. % of at least one reinforcing element, selected from a group comprising copper, chromium, magnesium, manganese, zinc and iron and aluminium as the remainder, at a temperature in the range of 350 to 550° C. until the silicon grains in the alloy powder grow to 6 to 12 μm, by mixing the first alloy powder with an aluminium base after the heating stage with a powder of a second alloy with an aluminium base, which contains at least one lubricant selected from a group consisting of lead, tin, indium and antimony and bismuth, so that the resulting alloy powder mixture has the same chemical composition as the bearing alloy to be produced, pressing the alloy powder mixture to a bar and flow press of the bar at a flow press ratio of not less than 10.

DE 37 29 414 A describes a layer material for slide bearing elements, e.g. radial slide bearings or axial slide bearings, consisting of a metal protective layer and an antifriction layer applied onto the support layer made of bearing material with an aluminium base, if necessary provided with an applied binding layer and adjustment layer, wherein the bearing material is a virtually homogenous aluminium alloy, which contains in the aluminium with the usual permissible impurities 1 to 3% mass portions of nickel, 0.5 to 2.5% mass portions of manganese and 0 to 2 mass portions of lead and can comprise hard particles of nickel and manganese or nickel-containing or manganese-containing hard particles, the particle size of which is substantially smaller than or equal to 5 μm, wherein the aluminium alloy forming the bearing material contains a bismuth additive of between 0.1 and 2% mass portions. In this way the production and processing should be improved by machine surface working and the sliding properties should be improved, in particular the emergency running properties of the bearing material provided for the antifriction layer.

Although it has been known to provide bismuth as an additive to bearing alloys or as frictional layers, until now no products have been available on the market, which is probably due to the fact that bismuth is brittle and thus difficult to process. Only in recent times has bismuth reappeared in slide bearings—mainly owing to the problems with lead mentioned above.

Thus for example DE 100 32 624 C describes a slide bearing, which comprises a bearing metal and a running layer formed on the bearing metal made of bismuth or a bismuth alloy, wherein the bismuth crystallites in this layer adopt a specific orientation, expressed by the X-ray diffraction levels. Said bismuth or bismuth alloy layer is produced by electrodeposition. In this way the fatigue strength and compatibility necessary for a running layer of a slide bearing should be improved.

DE 10 2004 025 560 B4 describes a sliding element, which comprises a bearing alloy layer and a bearing layer, which is formed on the bearing alloy layer, wherein the bearing layer is made from a bismuth-based alloy, which comprises copper in 0.1 to 10 wt. % and tin and/or indium with overall 0.5 to 10 wt. %.

DE 10 2004 045 110 B3 describes a sliding layer for slide bearings, in particular for crank shafts or connecting rod bearings, consisting of an alloy with several phases which form a matrix and a disperse phase, wherein the disperse phase has low solubility in the metal of the matrix, wherein the metal matrix is formed by an aluminium alloy and the disperse phase by bismuth or a high-melting bismuth alloy as well as a sputtering method for production. The bismuth content in the entire sliding layer can be between 10 and 40 wt. %, wherein bismuth or the bismuth alloy can be found distributed so finely that they are X-ray amorphous or in that their primary phases are not identifiable in by light microscope. With the exception of the reference to an eutectic in the bismuth-aluminium-system said document DE-B does not discuss how this fine grain is achieved.

DE 10 2004 055 228 A 1 describes a bearing shell of a connecting rod which is arranged in a large connecting rod eye, wherein the bearing shell is formed by several thermally injected layers and the uppermost material layer of the bearing shell is formed substantially from an aluminium/bismuth-alloy. Likewise the entire bearing shell can be formed substantially from a thermally injected layer of an aluminium-bismuth-alloy. It is described therein that bismuth is so finely distributed that it is X-ray amorphous, and the primary phases cannot be identified by light microscope. The bismuth content of the aluminium-bismuth-alloy can be between 10 and 40 wt. %. This very fine structure with a defined disperse phase of bismuth or a bismuth alloy is achieved by a very rapid cooling after formation at a raised temperature. However, this has the disadvantage that the method can only be controlled to a limited degree, in that an attempt is made to set these high cooling rates more or less precisely.

Lastly, DE 10 2005 050 374 A describes a method of producing a sliding layer, which consists of an aluminium alloy with the main alloy component bismuth and/or tin, copper and silicon, by means of PVD, CVD or sputtering, by depositing the alloy components from the vapour phase in fine-crystalline form or amorphous form onto a substrate, heat treatment of the deposited layer, wherein the temperature and duration of the heat treatment is selected such that the silicon recrystallises and grain size increases and thus coarse-crystalline silicon deposits are formed. In this way the pressure, temperature and long-term stability requirements of sliding layers should be improved, in particular a low wear rate should be achieved, an inexpensive production method should be possible. It is essential for this sliding layer that the silicon-depositions are coarse crystalline and in that bismuth acts not like silicon as a hard material, but as a lubricant. The bismuth content can be between 10 and 35 wt. %. This DE-A also leaves open the method by which the finely disperse distribution of the bismuth phase is achieved. In particular, the heat treatment for increasing the grain size of the silicon, is a problem with respect to the grain fineness of the bismuth.

It is therefore the objective of the present invention to provide a method of producing a sliding layer of a slide bearing element with a proportion of bismuth which has high-wearing resistance.

This objective of the invention is achieved by means of the aforementioned method of producing a slide bearing element, in which by means of the vapour-phase deposition of at least one element, the melting point of which is at least 950° C. higher than that of bismuth, and/or by applying a bias-voltage to the support element the bismuth nuclear density is increased, and independently of this by means of the slide bearing element, which in the aluminium matrix comprises at least one element, the melting point of which is at least 950° C. greater than that of bismuth.

It is an advantage in this case that by increasing the nuclear density of the bismuth a finer structure can be obtained, by means of which also the roughness of the layer can be reduced and as a result the wearing resistance of said sliding layer is increased. This can be achieved in that an element is added which has very low mobility and thus restricts the mobility of the bismuth, such as for example molybdenum,—the low mobility is also achieved mainly because elements with a high-melting point are added—or an element, which has a certain affinity to bismuth, whereby there can be an increase in the nuclear spaces, or by applying a bias voltage to the support element, so that as a result the number of lattice errors in the deposited layer is increased and thus more active centres are provided on which bismuth can crystallise.

Preferably an element is added, the melting point of which is at least 1,500° C. higher than that of bismuth, in particular an element whose melting point is 2,000° C. higher than that of bismuth.

The advantage of this is that a bismuth nuclear density is produced which is selected from a range with a lower limit of 4.10⁶ nuclei/cm² and an upper limit of 2.5.10⁹ nuclei/cm², as by way of the invention it has been established that a nuclear density from this range leads to a particular improvement in the wearing resistance.

The bismuth nuclear density can also be selected from a range with a lower limit of 4.10⁶ nuclei/cm² and an upper limit of 2.10⁸ nuclei/cm², or a range with a lower limit of 8.10⁶ nuclei/cm² and an upper limit of 6.10⁷ nuclei/cm².

This also applies if the bias voltage at the support element is selected from a range with a lower limit of 20 V and an upper limit of 150 V.

The bias voltage can also be selected form a range with a lower limit of 30 V and an upper limit of 120 V, or from a range with a lower limit of 45 V and an upper limit of 100 V.

Particularly in association with the added element with the applied bias voltage these effects could be improved further.

The at least one element with the higher melting point than bismuth is added to the vapour phase preferably at the same time as the bismuth, as in this way by controlling the target from the element the deposition rate of the element can be varied, whereby a direct influence on the number of nuclei, i.e. the nuclear density, can be achieved.

It is also an advantage if the at least one element with the higher melting point than bismuth is added in a concentration of the vapour phase which is selected from a range with a lower limit of 1% and an upper limit of 10%. With these concentrations of this element high concentrations of bismuth can be achieved with suitably positive properties with respect to the wearing resistance of said layer as well as the sliding properties in themselves.

The at least one element with the higher melting point than bismuth can also be added in a concentration of the vapour phase, which is selected from a range with a lower limit of 2% and an upper limit of 7.5%, in particular selected from a range with a lower limit of 3.25% and an upper limit of 6.15%.

It is also possible that the copper, which is possibly added to the aluminium matrix to form hard phases and thus for matrix reinforcement, is replaced at least partly by the at least one element with a higher melting point than bismuth, as in this way this element contributes not only to the grain refining, but also to the reinforcement of the matrix itself. In particular, this affects elements which can form intermetallic phases with bismuth, for example nickel, the matrix-strengthening properties for aluminium are known from the prior art. Thus in comparison to conventional aluminium-matrix alloys which do not contain bismuth only a slight modification of the alloys is necessary.

According to a development of the slide bearing element the bismuth containing phase has a grain size which is selected from a range with a lower limit of 50 nm and an upper limit of 3 μm. Essentially this is a result of the aforementioned, preferred nuclear density, whereby the mentioned wearing resistance can be improved. By increasing the amount of the element with the higher melting point than bismuth the grain size of the bismuth phase can be reduced or increased by reducing this amount. Thus very fine layers can be achieved with higher amounts of elements with a higher melting point than bismuth.

The bismuth containing phase can also have a grain size, selected from a range with a lower limit of 250 nm and an upper limit of 2 μm, in particular selected from a range with a lower limit of 500 nm and an upper limit of 1.5 μm.

The at least one element, which is added to the aluminium matrix, is preferably selected from a group comprising molybdenum, nickel, manganese, chromium, iron, hafnium, carbon, niobium, iridium, osmium, rhenium, rhodium, ruthenium, tantalum, vanadium, tungsten, technetium and titanium. These elements partly have a high melting point, whereby they can significantly impair the mobility of bismuth, i.e. its surface diffusion during the production of the slide bearing element, and in this way the nuclear density can be set to be suitably high.

By means of the high nuclear density it is possible to incorporate portions of bismuth in the sliding layer of up to an upper limit of 45 wt. %. In particular, the amount of bismuth in the sliding layer is between 10 wt. % and 45 wt. %. By means of these high portions of bismuth in the sliding layer the use of bismuth for this purpose is improved significantly as a replacement for lead and tin.

It is possible within the scope of the invention for the proportion of bismuth to be selected from a range with a lower limit of 20 wt. % and an upper limit of 45 wt. % or from a range with a lower limit of 25 wt. % and an upper limit of 45 wt. %.

Furthermore, it is possible to select the proportion of copper from a range with a lower limit of 0.5 wt. % and an upper limit of 5 wt. % in order to achieve sufficient matrix strengthening of the aluminium matrix and thus be able to adjust the hardness of said sliding layer accordingly. In this case it is possible within the scope of the invention to select the proportion of copper from a range with a lower limit of 1 wt. % and an upper limit of 2.5 wt. %, whereby in the latter range the properties of the sliding layer are particularly effective with respect to wearing resistance and sliding ability.

The proportion of the at least one element is preferably selected from a range with a lower limit of 0.5 wt. % and an upper limit of 10 wt. %, with the proviso that the sum of several elements from this group does not amount to more than 15 wt. %. Below the given limit no sufficient increase in the bismuth nuclear density could be observed so that the improvement of the wearing resistance was insufficient. Above the given limit further additions of at least one of these elements showed no further improvement in the wearing resistance and only caused a reduction in the bismuth content or an excessive increase in the hardness of the sliding layer, whereby the sliding properties of the sliding layer were made worse.

In particular, the proportion of the at least one element is selected from a range with a lower limit of 2.5 wt. % and an upper limit of 8 wt. %, preferably from a range with a lower limit of 3.25 wt. % and an upper limit of 7.15 wt. %.

The sliding layer preferably has a layer thickness which is selected from a range with a lower limit of 10 μm and an upper limit of max. 150 μm. Layer thicknesses below this limit can, particularly if the grain size of the bismuth crystallites lies in the lower part of the aforementioned range, possibly worsen the wearing resistance by very rapid abrasion. Layer thicknesses above the given range can be applied partly in principle, but it may occur that the cohesiveness of the sliding layer worsens and thus premature wear occurs.

In particular according to one embodiment variant a layer thickness of the sliding layer is produced, which is selected from a range with a lower limit of 12 μm and an upper limit of 80 μm, preferably from a range with a lower limit of 20 μm and an upper limit of 30 μm.

It is also an advantage within the scope of the invention if the sliding layer has a Vickers hardness which is selected from a range with a lower limit of 50 UMHV(3 pond) and an upper limit of 250 UMHV(3 pond). In particular sliding layers with hardnesses from this range have proved advantageous as a substitute for lead-containing sliding layers. If the hardness of the sliding layer falls below the given range the sliding layer no longer has the desired wearing resistance. If however the sliding layer has a hardness above the given value the latter is too hard, whereby the wearing resistance of the sliding layer is improved but increased abrasion on the component to be supported can be observed and in particular also the running properties can also be impaired due to insufficient lubrication.

In particular the Vickers hardness can be selected from a range with a lower limit of 70 UMHV (3 pond) and an upper limit of 230 UMHV (3 pond), preferably from a range with a lower limit of 85 UMHV (3 pond) and an upper limit of 200 UMHV (3 pond).

The hardness parameters relate to a Vickers-ultramicro-hardness measurement with a test force of 3 pond according to the standard DIN EN ISO 6507-1.

Owing to the fine grain of the bismuth crystallites or the crystallites of bismuth phases it can occur that the bismuth diffuses increasingly into the underlying layers due to the temperature of the slide bearing elements. In this case it is an advantage if as a diffusion barrier layer between the sliding layer and an underlying bearing metal layer a layer of steel, in particular high-quality steel is arranged, as such diffusion barrier layers are more effective than conventional diffusion barrier layers made of iron or nickel by avoiding the formation of intermetallic phases with said diffusion barrier layer.

For a better understanding of the invention the latter is explained in more detail with reference to the following Figures and exemplary embodiments.

In a much simplified representation:

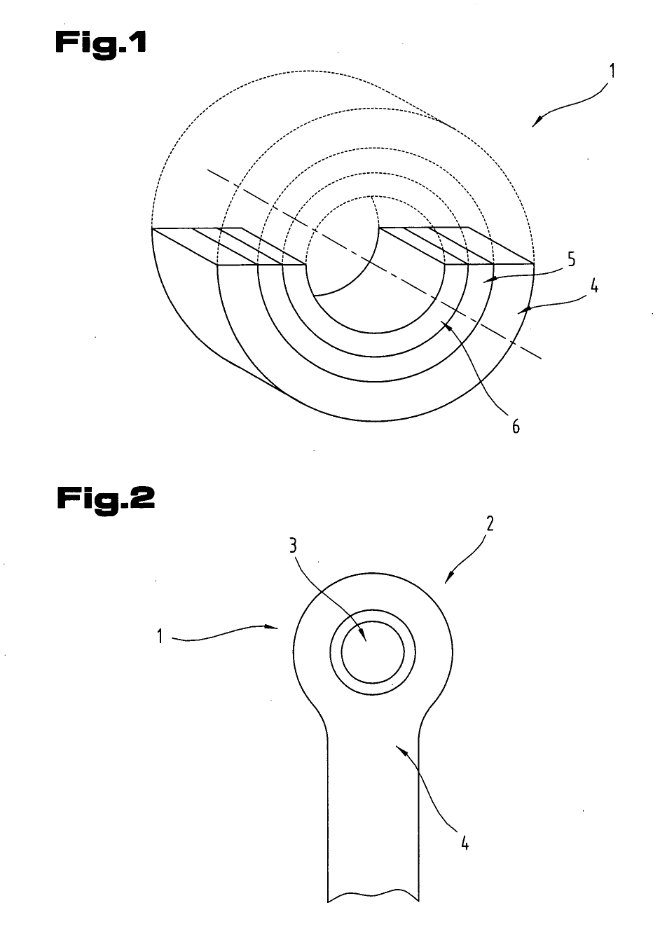

FIG. 1 shows a slide bearing element in the form of a slide bearing half shell or full shell;

FIG. 2 shows the direct coating of a connecting rod eye of a connecting rod.

First of all, it should be noted that in the variously described exemplary embodiments the same parts have been given the same reference numerals and the same component names, whereby the disclosures contained throughout the entire description can be applied to the same parts with the same reference numerals and same component names. Also details relating to position used in the description, such as e.g. top, bottom, side etc. relate to the currently described and represented figure and in case of a change in position should be adjusted to the new position. Furthermore, also individual features or combinations of features from the various exemplary embodiments shown and described can represent in themselves independent or inventive solutions.

All of the details relating to value ranges in the present description are defined such that the latter include any and all part ranges, e.g. a range of 1 to 10 means that all part ranges, starting from the lower limit of 1 to the upper limit 10 are included, i.e. the whole part range beginning with a lower limit of 1 or above and ending at an upper limit of 10 or less, e.g. 1 to 1.7, or 3.2 to 8.1 or 5.5 to 10.

FIG. 1 shows a slide bearing element 1 according to the invention in the form of a slide bearing half-shell.

Is should be mentioned at this point that the invention is not limited to slide bearing elements 1 in the form of slide bearing half shells, but rather also incorporates other slide bearing elements 1, such as e.g. starting rings, full shell bearing elements, as indicated by a dashed line in FIG. 1, bearing bushes, as well as directly coated applications, such as e.g. connecting rod bearings 2, i.e. a connecting rod eye 3, as represented in FIG. 2 etc. The slide bearing elements 1 can be designed in the form of radial or axial bearings.

The slide bearing element 1 according to FIG. 1 is constructed from a support element 4 or a support shell, a bearing metal layer 5 and a sliding layer 6. The support element 4 is usually made of steel, but can of course also be made from comparable materials, by means of which the same or a similar function, namely the mechanical strength of the slide bearing element 1, can be provided. The mechanical strength of the entire slide bearing element 1 is thus dependent on the respective area of use, so that for example also different copper alloys, such as e.g. brass or bronze can be used. In addition, a certain degree of form-stability is ensured by the support element 4.

It should be noted that it is not absolutely necessary within the scope of the invention for a bearing metal layer 5 to be arranged between the sliding layer 6 and the support element 4, but rather the sliding layer 6 can be arranged directly on the support element 4. For example this is the case, if e.g. connecting rod bearings 2 are coated directly, i.e. the connecting rod eye 3 of a connecting rod.

The bearing metal layer 5 can consist in principle of all bearing metals known from the prior art for such slide bearing elements 1, whereby the latter are preferably lead-free. Examples are:
1. bearing metals with an aluminium base (partly according to DIN ISO 4381 or 4383): AlSn6CuNi, AlSn20Cu, AlSi4Cd, AlCd3CuNi, AlSi11Cu, AlSn6Cu, AlSn40, AlSn25CuMn, AlSi11CuMgNi, AlZn4,5;
2. bearing metals with a copper base (partly according to DIN ISO 4383): CuSn10, CuAl10Fe5Ni5, CuZn31Si, CuSn8Bi10, CuSn2,5-11Zn0,5-5, z.B. CuSn4,5Zn;

Furthermore, it is possible as is already known from the prior art, to arrange between the individual bands or at least the individual layers, i.e. for example the support element 4 and the bearing metal layer 5 and/or the bearing metal layer 5 and/or the sliding layer 6, at least one intermediate layer in the form of a bonding layer or also as a diffusion barrier layer, in order to prevent the diffusion of individual components caused by the thermal charging of the slide bearing element 1 from one layer to another layer, and thus prevent the depletion of a layer on this element, and in order to improve the adhesive strength of the individual layers. The binding layers can for example be layers made of pure aluminium or aluminium alloys, for example alloys of aluminium with scandium. Diffusion barrier layers can be formed for example by nickel, copper or silver layers. In particular, preferably with regard to the presence of bismuth a diffusion barrier layer made of steel, in particular high-quality steel, is used.

Said binding or diffusion barrier layers usually have a small layer thickness of 1 to 3 μm.

The bearing metal layer 5 can have a layer thickness selected from a range with a lower limit of 100 μm and an upper limit of 1 mm, the support element 4 can have a layer thickness selected from a range with a lower limit of 1 mm and an upper limit of 7 mm.

According to the invention the sliding layer 6 is formed from an aluminium base alloy with an aluminium matrix, in which as well as aluminium bismuth forms the main component of the alloy. If necessary copper can also be included for matrix strengthening.

The slide bearing element 1 is lead-free in particular, i.e. there is no lead in either the bearing metal layer 5 or the sliding layer 6. The term lead-free in the invention means that no additional lead is added, however traces of lead may be found owing to impurities from the manufacturing process of the individually used elements, unless extremely pure elements are used.

The production of the sliding layer 6, i.e. the deposition onto the support element 4 or the bearing metal layer 5 or a diffusion barrier layer or binding layer arranged in between is performed from the vapour phase, preferably by sputtering. As the sputtering method is already known from the prior art, reference is made to the relevant prior art concerning the design and arrangement of the target, the arrangement of the components to be coated in the coating chamber etc.

Also the diffusion barrier layer made of steel, in particular high-quality steel, is preferably sputtered on.

The bearing metal layer 5 and/or additional intermediate layers can be deposited galvanically if necessary and it is possible to bind the latter by means of roll cladding to the support element 4 or in particular to apply the latter by means of a casting method, in particular horizontal continuous casting.

Also these methods have already been documented sufficiently in the prior art, so that they need not be discussed in more detail here.

For admixing the at least one element, which has a melting point at least 950° C. higher than bismuth, it is possible to produce a target from these elements and it is also possible to produce a corresponding target from a prealloy with bismuth or aluminium. Thus pure metals or prealloys can be used within the scope of the invention.

It is also possible for several, for example two, three or four of the aforementioned elements with the higher melting point to be included in the sliding layer 6 and for this corresponding prealloys consisting of several elements or also several individual targets can be used. Said elements are preferably metallic and not radioactive.

In this case it is also possible for the individual targets, if several elements are used in the form of individual targets, to be charged with energy alternately, so that in the vapour phase different concentrations of these elements are available alternately and thus primarily these elements are deposited in layers on the support element 4 or the bearing metal layer 5, whereby if necessary fluctuations in concentrations can be balanced out, if this is desired and no concentration gradients are set in the sliding layer 6 on the individual elements, for example by different hardnesses in the region of the surface of the sliding layer, which points to the component to be mounted e.g. a shaft and there can be a greater hardness in the region of the bearing metal layer 5 by diffusion due to the heat charging during production.

As the experiments that the Applicant carried out within the scope of the invention would exceed the scope of this description only selected exemplary embodiments of the invention are described in the following.

### 1. Exemplary Embodiment

A strip of steel was coated with a bearing metal layer 5 made of cast CuSn5Zn by horizontal strip casting and said composition was then shaped into the form of a slide bearing half-shell. Said slide bearing half-shell was then moved into a coating chamber of a testing installation which was then evacuated. If necessary, the coating chamber can be rinsed several times with argon after transferring the slide bearing half-shell and evacuated in between.

After the transfer the surface was cleaned by inverse sputtering with Ar as the processing gas.

As a target for sputtering the sliding layer 6 an, in particular powder-metallurgically produced alloy target made of molybdenum, aluminium and bismuth was used. The following parameters were used for the coating:

temperature: 150° C.

pressure: 2.10⁻³ mbar

power: 4 kW

deposit rate: 0.85 μm/Min

The sliding layer 6 had the final composition AlBi15Mo2.

A thickness of the sliding layer 6 of 16 μm was produced.

In one embodiment variant for this an intermediate layer of high-quality steel was arranged on the bearing metal layer 5 prior to the deposition of the sliding layer 6.

Molybdenum has a melting point of about 2,620° C., which is thus much higher than the melting point of bismuth, which is about 271° C. Because of this high melting point the molybdenum is subjected to practically no diffusion in the sliding layer 6 during the coating, so that in this way for the adhering bismuth atoms there is only limited space for the diffusion, i.e. in this way the surface diffusion of the bismuth is restricted. Thus it is prevented that several bismuth atoms—over time—bind to greater dispersal phases, and the latter form individual bismuth crystallites or bismuth atoms nuclei for further bismuth atoms, whereby by preventing the diffusion a large number of nuclei are provided—with respect to the nuclear density refer to above description—and thus a much finer structure can be produced.

Almost the same operative mechanism is exhibited for example by carbon, in particular diamond, with a melting temperature of about 3,547° C., tungsten with a melting temperature of 3,422° C., rhenium with a melting temperature of 3,186° C., osmium with a melting temperature of 3,033° C., tantalum with a melting temperature of 3017° C., niobium with a melting temperature of 2,477° C., iridium with a melting temperature of 2,446 ° C., ruthenium with a melting temperature of 2,334° C., hafnium with a melting temperature of 2233° C., technetium with a melting temperature of 2,157° C. This effect could also be observed with other metallic elements below 2,000° C., for example palladium or platinum, wherein it could be observed that this effect is greater with the given metal elements, the melting point of which is at least 1,500° C., or at least almost 2,000° C. higher than that of bismuth.

### 2. Exemplary Embodiment

With the exception of the sliding layer 6 the same structure of the slide bearing element 1 was used as in exemplary embodiment 1.

Instead of molybdenum in this case nickel was used as the alloy element in the target, whereby in this case copper was also used in order to harden the aluminium matrix, whereby in comparison to usual concentrations of copper from the prior art for this purpose only half of the amount of copper was added and the other half was replaced by nickel. The following parameters were used for the coating.

temperature: 150° C. pressure: 2.5.10⁻³ mbar power: 4.5 kW deposit rate: 0.8 μm/Min

The sliding layer 6 had the final composition AlBi11Cu0.5Ni0.5

The thickness of the sliding layer 6 was 20 μm.

Bismuth forms with nickel limited intermetallic phases, for example in NiBi or NiBi3. In this way by adding nickel a greater number of possible nuclei spaces is provided for the bismuth for deposition, whereby a finer structure is obtained—with respect to the grain sizes reference is made to the above explanations. In addition, nickel has a strengthening effect on the aluminium matrix, so that with nickel or similarly acting elements, such as for example manganese, a double effect can be achieved with respect to the wearing resistance of the sliding layer 6.

It should be mentioned at this point that it is possible within the scope of the invention to use both effects according to the exemplary embodiment 1 and 2, i.e. to add to the aluminium base alloy both a metal element with a very high melting point as well as an element which has a certain affinity to bismuth.

### 3. Exemplary Embodiment

To increase the nuclear density and thus achieve a finer structure, a bias voltage of −50 V was applied to the substrate, i.e. the support element 4, with the background during the deposition of aluminium and bismuth of producing lattice errors, whereby said lattice error form active centres and thus nuclei points. In this case the following parameters were used.

temperature: 175° C.

pressure: 2.10⁻³ mbar

power: 4.5 kW

deposit rate: 0.8 μm/Min

The sliding layer 6 had the final composition AlBi25Cu.

In this way a thickness of the sliding layer 6 of 15 μm was produced.

Furthermore, it should be mentioned that it is possible within the scope of the invention for the production of a slide bearing element 1, i.e. in particular a sliding layer 6, to use all three effects according to the exemplary embodiments 1 to 3 or only two effects according to the exemplary embodiments 1 and 3 or 2 and 3.

The sliding layer 6 and the bearing structure according to the invention can be used in particular for lorry bearings.

The exemplary embodiments show possible embodiment variants of the slide bearing element 1, whereby it should be noted at this point that the invention is not restricted to the embodiment variants shown in particular, but rather various different combinations of the individual embodiment variants are also possible and this variability, due to the teaching on technical procedure, lies within the ability of a person skilled in the art in this technical field. Thus all conceivable embodiment variants, which are made possible by combining individual details of the embodiment variants shown and described, are also covered by the scope of protection.

Finally, as a point of formality, it should be noted that for a better understanding of the structure of the slide bearing element 1 the latter and its components have not been represented true to scale in part and/or have been enlarged and/or reduced in size.

The problem addressed by the independent solutions according to the invention can be taken from the description.

Mainly the individual embodiments shown in FIGS. 1; 2 can form the subject matter of independent solutions according to the invention. The objectives and solutions according to the invention relating thereto can be taken from the detailed descriptions of these figures.

### List of Reference Numerals

1 slide bearing element
2 connecting rod bearing
3 connecting rod eye
4 support element
5 bearing metal layer
6 sliding layer

1. Method of producing a slide bearing element (1) according to which a sliding layer (6) is produced on a support element (4) by vapor-phase deposition, if necessary after the insertion of at least one intermediate layer, wherein the sliding layer (6) comprises an aluminum matrix, which in addition to aluminum contains bismuth as a main component and possibly copper and also impurities of the elements arising during production, wherein by means of the vapor-phase deposition of at least one element, the melting point of which is at least 950° C. higher than that of the bismuth and/or by applying a bias-voltage to the support element the bismuth-nuclear density is increased.

2. Method according to claim 1, wherein the bismuth-nuclear density is set at a level selected from a range with a lower limit of 4.10⁶ nuclei/cm² and an upper of 2.5.10⁶ nuclei/cm².

3. Method according to claim 1, wherein the bias-voltage at the support element is selected from a range with a lower limit of −20 V and an upper limit of −150 V.

4. Method according to claim 1, wherein the at least one element with a higher melting point than bismuth is added to the vapor phase at the same time as the bismuth.

5. Method according to claim 1, wherein the at least one element with the higher melting point than bismuth is added in a concentration to the vapor phase selected from a range with a lower limit of 0.5% and an upper limit of 10%.

6. Method according to claim 1, wherein the copper is replaced at least partly by the at least one element with the higher melting point than bismuth.

7. Slide bearing element (1) with a support element (4), on which a sliding layer (6) deposited from the vapor phase is arranged and if necessary at least one intermediate layer is arranged between the support element (4) and the sliding layer, wherein the sliding layer (6) comprises an aluminum matrix, which in addition to aluminum contains bismuth with the formation of a bismuth-containing phase as the main component and possibly copper and the unavoidable impurities in the elements arising from production, wherein in the aluminum matrix at least one element is included, the melting point of which is at least 950° C. higher than that of bismuth.

8. Slide bearing element (1) according to claim 7, wherein the bismuth-containing phase has a grain size, which is selected from a range with a lower limit of 50 nm and an upper limit of 3 μm.

9. Slide bearing element (1) according to claim 7, wherein the at least one element is selected from a group comprising molybdenum, nickel, manganese, chromium, iron, hafnium, carbon, niobium, iridium, osmium, rhenium, rhodium, ruthenium, tantalum, vanadium, tungsten, technetium and titanium.

10. Slide bearing element (1) according to claim 7, wherein the proportion of bismuth is selected from a range with a lower limit of 10 wt. % and an upper limit of 45 wt. %.

11. Slide bearing element (1) according to claim 7, wherein the proportion of copper is selected from a range with a lower limit of 0.5 wt. % and an upper limit of 5 wt. %.

12. Slide bearing element (1) according to claim 7, wherein the proportion of the at least one element is selected from a range with a lower limit of 0.5 wt. % and an upper limit of 10 wt. %, with the proviso that the sum of several elements from this group does not amount to more than 15 wt. %.

13. Slide bearing element (1) according to claim 7, wherein the sliding layer (6) has a layer thickness, which is selected from a range with a lower limit of at least 10 μm and an upper limit of a maximum of 150 μm.

14. Slide bearing element (1) according to claim 7, wherein the sliding layer (6) has a Vickers hardness, selected from a range with a lower limit of 50 UMHV (3 pond) and an upper limit of 250 UMHV (3 pond).

15. Slide bearing element (1) according to claim 7, wherein on the support element (4) a bearing metal layer (5) and over the latter the sliding layer (6) and between the bearing metal layer (5) and the sliding layer (6) a diffusion barrier layer made of steel, in particular high-quality steel, are arranged.
